(19) United States
(12) Patent Application Publication
(10) Pub. No.: US 2007/0243620 A1
(43) Pub. Date: Oct. 18, 2007

(54) Analysis and Screening of Solid Forms Using the Atomic Pair Distribution Function

(76) Inventors: Simon Bates, West Lafayette, IN (US); Igor Ivanisevic, West Lafayette, IN (US)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 10/590,204

(22) PCT Filed: Feb. 24, 2005
(86) PCT No.: PCT/US05/06114

§ 371 Date: May 4, 2007

Related U.S. Application Data
(60) Provisional application No. 60/546,976, filed on Feb. 24, 2004.

(51) Int. Cl. G01N 23/20; G06F 19/00; G11C 17/00

(52) U.S. Cl. 436/57; 365/94; 702/19

(57) ABSTRACT

A method that comprises providing a PDF trace of a first sample of a substance, providing a PDF trace of a second sample of the substance, and comparing the PDF traces to determine whether the substance of the first sample and the substance of the second sample have the same or different solid forms. This embodiment may be used, for example, to distinguish one solid form of a compound from another, to screen for new solid forms of a compound, or to determine whether a disordered crystalline compound has the same solid form as another crystalline sample of the compound.

### CROSS-REFERENCE TO RELATED APPLICATIONS

This application claims the benefit of priority to U.S. Provisional Application No. 60/546,976, filed on Feb. 24, 2004, the contents of which are incorporated by reference herein.

### SUMMARY OF THE INVENTION

This invention relates to the analysis and screening of solid forms using the atomic pair distribution function (“PDF”). One embodiment of the invention is a method that comprises providing a PDF trace of a first sample of a substance, providing a PDF trace of a second sample of the substance, and comparing the PDF traces to determine whether the substance of the first sample and the substance of the second sample have the same or different solid forms. The PDF trace is derived from the X-ray powder diffraction (“XRPD”) pattern of the solid substance.

This and other embodiments of the invention may be used, for example, to distinguish one solid form of a compound from another, to screen for new solid forms of a compound, or to determine whether a disordered crystalline compound has the same solid form as another crystalline sample of the compound. The embodiments of the invention may be applied, for example, to a substance that is a chemical compound, for instance a pharmaceutical compound. The embodiments of the invention may also be applied, for example, to a substance that is a mixture of chemical compounds, for instance a co-crystal.

Additional objects and advantages of the invention are set forth in the following description. Both the foregoing general summary and the following detailed description are exemplary only and are not restrictive of the invention as claimed. Further features and variations may be provided in addition to those set forth in the description. For instance, the present invention includes various combinations and subcombinations of the features disclosed in the detailed description.

### BRIEF DESCRIPTION OF THE DRAWINGS

The accompanying drawings, which are incorporated in and constitute a part of this specification, illustrate several embodiments of the invention and, together with the description, serve to explain certain principles of the invention.

FIG. 1 illustrates a block diagram of an exemplary system environment consistent with the present invention.

FIG. 2 illustrates XRPD patterns of a disordered crystalline solid substance (top) and a highly crystalline solid substance (bottom).

FIG. 3 illustrates PDF traces of the highly crystalline solid substance (top) and the disordered crystalline solid substance (bottom) having the same solid form.

FIG. 4 illustrates XRPD patterns of a substance before cryogrinding (top), after 12 minutes of cryogrinding (middle) and after 30 minutes of cryogrinding (bottom).

FIG. 5 illustrates PDF traces of a substance before cryogrinding (top), after 12 minutes of cryogrinding (middle) and after 30 minutes of cryogrinding (bottom).

### DETAILED DESCRIPTION OF THE INVENTION

This invention relates to the analysis and screening of substances in solid form using the PDF. The substances used in the invention include chemical compounds, for example, pharmaceutical compounds. They include salts of chemical compounds, for instance pharmaceutical compounds as pharmaceutically acceptable salts. They also include mixtures of two or more chemical compounds, for instance cocrystals.

The substances of the invention include amorphous solid forms as well as crystalline solid forms. They may be, for example, cocrystals, hydrates, solvates, polymorphs, dehydrated hydrates, desolvated solvates, molecular complexes, and clathrates. The term “crystalline” as used herein includes polycrystalline, microcrystalline, nanocrystalline, mesocrystalline, liquid crystalline, mesophases, and partially or wholly crystalline substances, as well as disordered crystalline substances.

The solid forms of the invention may be generated in any suitable manner. For example, a plurality of samples of a substance can be generated in capillary tubes or in wells of a well-plate. The samples may be crystallized in different environments, for instance using different solvents, different temperatures, different humidities, or different pressures. One skilled in the art will appreciate the variety of approaches that may be taken to generate different solid forms of a substance.

The PDF trace is derived from the XRPD pattern of a solid form. An X-ray powder diffractometer such as the Siemens D-500 X-ray Powder Diffractometer-Kristalloflex and the Shimadzu XRD-6000 X-ray powder diffractometer, using Cu-Ka radiation, may be used to generate an XRPD pattern.

An embodiment of the invention is a method that comprises providing a PDF trace of a first sample of a substance, providing a PDF trace of a second sample of the substance, and comparing the PDF traces to determine whether the substance of the first sample and the substance of the second sample have the same or different solid forms.

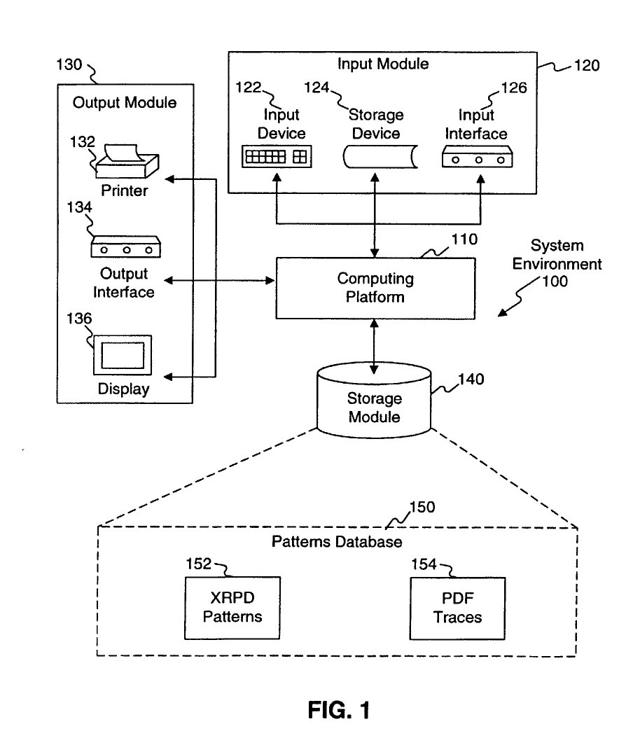

This and other embodiments of the invention may be performed in a system environment such as one illustrated in FIG. 1. Computing platform 110 may be adapted to process input information received from input module 120. Computing platform 110 may be further adapted to provide output information to output module 130. Additionally, computing platform 110 may be adapted to access data stored in storage module 140.

In performing methods consistent with the present invention, PDF traces of substances can be provided in computing platform 110. Computing platform 110 may comprise, for example, a general purpose computer (e.g., a personal computer, network computer, server, mainframe computer, etc.) having a processor that may be selectively activated or configured by a computer program to perform one or more methods consistent with the present invention. Alternatively, computing platform 110 may be specifically constructed to carry out methods consistent with the present invention. Computing platform 110 may be implemented on a single platform, such as a stand-alone computer. Alternatively, computing platform 110 may be implemented on a distributed network, such as a network of computers connected, e.g., by a LAN, WAN, etc., or the Internet.

In one embodiment, the PDF trace of a substance may be provided to computing platform 110 from input module 120. In another embodiment, the XRPD pattern of a substance may be provided to computing platform 110 from input module 120, and computing platform 110 calculates the PDF trace from the XRPD pattern.

The PDF traces or XRPD patterns may be received from, for example, storage device 124 or a computer readable medium or media linked to input interface 126. Computing platform 110 may then store any information received from input module 120 in storage module 140.

Input module 120 may include an input device 122, a storage device 124, and/or an input interface 126. Input device 122 may be implemented using any user interface adapted for data entry. For example, input device 122 may be implemented using a keyboard, mouse, speech recognition device, etc. Storage device 124 may include a computer readable medium or media that contains instructions to configure computing platform 110 to perform one or more methods consistent with the present invention.

A computer readable medium may be any type of media (e.g., RAM, ROM, etc.) that is capable of carrying information that may be used to configure computing platform 110 to perform methods consistent with the present invention. For example, computer readable media may be implemented using physical media (e.g., a punch card), magnetic media (e.g., a magnetic disk or tape), optical media (e.g., an optical disk), a carrier wave (e.g., from a computer network, such as the Internet), etc.

Computing platform 110 may calculate the PDF trace from an XRPD pattern as detailed in Peterson et al., “Improved measures of quality for the atomic pair distribution function,” J. Appl. Cryst., vol. 36, pp. 53-64 (2003), the contents of which are incorporated by reference herein. By definition, the PDF is the instantaneous atomic density-density correlation function, which describes the atomic arrangements in materials. It is the sine (imaginary) Fourier transform of the experimentally determined reduced structure factor obtained from a measured powder pattern. Since the total structure factor contains both the Bragg intensities and the diffuse scattering its Fourier associate, the PDF may yield both the local and average atomic structure of materials.

The first step in the calculation of the PDF trace is the derivation of the total structure factor S(Q) from the measured XRPD pattern. All instrumental and known thermal contributions to the measured intensity in the XRPD pattern should be removed from the measured intensity along with the true instrumental background. Removal of the true instrumental background is desired, since one should not remove any diffuse scattering or broad intensity features generated by the sample of interest.

The instrumentally corrected data is converted into Q-space and then reduced to remove the average electronic form factor. The rapid fall off of the electronic form factor for organic molecular solid forms is the primary reason why X-ray diffraction data only need be collected out to 40 or 60 degrees 2Theta (using Cu-kalpha) and why therefore laboratory sources are sufficient to generate a reasonable PDF trace for these materials. The removal of the electronic form factor gives the total structure factor S(Q):
S(Q)=1+[Ic(Q)−sum(cᵢfᵢ(Q)²)]/sum(cᵢfᵢ(0)²),
where Ic(Q) is the corrected measured data as a function of Q, cᵢ is the concentration of each atom type present and fᵢ(Q) is the individual atomic form factor.

The form factor expression above may be difficult to evaluate for large organic molecules and can therefore often approximated by the following equation:
Sum(cᵢfᵢ(Q)²)==>weight exp(−Q²/width),
with the vales of weight and width being automatically selected to give a structure factor S(Q) that asymptotically approaches 1 at the largest Q values.

Once S(Q) has been determined, it can be converted into the reduced structure factor F(Q) through the following expression:
F(Q)=Q*[S(Q)−1].
The operator or algorithm may then validate the nature of the reduced structure factor. In this regard, the large molecule scale factors of density (weight) and size(width) mentioned above can be varied to give a reduced structure factor with the appropriate form. At the largest Q values of the measurement, the reduced structure factor should approach zero asymptotically with no abrupt truncation. Furthermore, the reduced structure factor is zero at zero Q and should exhibit a general trend that smoothly drops negative before slowly rising towards positive values. The sum of Q*F(Q) over a valid experimental region should be normalized to give the constant value −2pi*average_number_density.

The operator or algorithm may then apply the PDF transform:

$$PDF = G ( r ) = \frac{2}{π} {\int }_{0}^{∞} Q [ S ( Q ) - 1 ] sin ( Qr ) ⅆ Q ,$$

where r is the distance between two atoms. In order to enhance the resolution of the PDF function in real space “r”, the sin transform can be evaluated over an artificial range of “r” values not determined by the measurement range. For example, the PDF can be reconstructed using an “r” step size of 0.2 Angstroms, which is equivalent to measuring out to 180 degrees 2Theta using an x-ray wavelength of 1.0 Angstroms. The resulting PDF is reconstructed over the range of inter atomic distances of interest and displayed in real space Angstroms.

To avoid significant disruption of the PDF trace by experimental artifacts, it is helpful to reduce possible sources of systematic error and any significant truncation in the measured diffraction intensity at high and low angles. An optimum strategy for avoiding intensity truncation is to measure over a large range in Q to trace the diffraction single to background. Fortunately, for the large majority of organic molecular solid forms, the X-ray diffraction intensity can be measured from the low angle background level to the high angle background level over a relatively small angular range easily accessed using standard laboratory X-ray diffraction systems. However, the reduced measurement range implies reduced sensitivity to small inter-atomic distances. The loss of this small distance information is likely not relevant to the determination of polymorph type or solid form differences, as this is determined by larger inter-molecular distances rather than the shorter intra-molecular distances.

In performing methods consistent with the present invention, PDF traces can be compared using computing platform 110. The PDF trace provides a unique finger-print of the inter-atomic distances that define a particular solid form. As such, it provides a valuable tool to match solid forms and, more particularly, to identify relationships between disordered crystalline and other crystalline substances.

If two solid forms have the same molecule and molecular packing, their PDF traces will be the same within experimental limitations. PDF peak positions correspond to atom—atom distances and the relative peak intensities correspond to the number of atoms having that specific separation. Both the peak positions and relative peak intensities should match between PDF traces of the same solid form, within experimental limitations. However, when matching crystalline and disordered crystalline substances, relative peak intensities of intermolecular peaks should be adjusted because of loss of order.

The degree of sameness between PDF traces should be determined using only those inter-atomic distances best defined by the measurement range and resolution. For laboratory measurements, the short inter-atomic distances <5.0 Angstroms can be disregarded. For matching crystalline solid forms, it is usually sufficient to only include inter-atomic distances out to the 3^{rd} or 4^{th} coordination sphere. When matching disordered forms, the maximum inter-atomic distance considered should be reduced to be consistent with the typical molecule to molecule coordination distance. This can be estimated a priori from the measured X-ray diffraction peak widths using the Scherrer equation, which relates the increase in peak width with crystal correlation length:
Correlation length (A)=(K lambda)/(beta cos(theta)),
where beta is the increase in peak width at half height in radians, theta is the Bragg angle of the broadened peak, lambda is the x-ray wavelength and K is a shape constant ˜0.9. For disordered forms, the PDF trace itself will rapidly drop to a constant value over very short distances, which can be as small as the first coordination sphere also for amorphous materials.

An automatic matching algorithm for PDF traces from laboratory X-ray powder diffraction data may be provided to score the degree of sameness by matching peak position and relative peak intensities over a range of inter-atomic distances from 5.0 Angstroms out to 50 Angstroms, for example. For disordered materials, the larger inter-atomic distance cut-off can be automatically reduced as the degree of disorder increases.

Results of operations performed by computing platform 110 may be stored, for example, in storage module 140. For instance, PDF traces may be stored in a PDF trace database 154, Results of the comparison of PDF traces may also be stored in storage module 140. Storage module 140 may be implemented as any appropriate type of computer readable medium or media. Storage module 140 may be used to store XRPD patterns in pattern database 150, for instance in XRPD patterns database 152.

PDF traces and results of the comparison of PDF traces may also be provided to output module 130. Output module 130 may include a printer 132, an output interface 134, and/or a display 136. Output interface 134 may be used to provide stored information or results to a user via a computer network, the Internet, or to save such information on a computer readable medium or media (not shown). Display 136 may provide information or results to the user of the system, e.g., via a computer screen.

Although embodiments of the invention have been discussed as comparing one PDF trace to another, one skilled in the art will appreciate from this disclosure that the invention does not exclude a comparison of more than two PDF traces. For example, the practice of the invention includes comparing one PDF trace to a plurality of other PDF traces, comparing a plurality of PDF traces to one PDF trace, comparing a plurality of PDF traces to each of a plurality of other PDF traces, and so forth.

Moreover, although embodiments of the invention have been discussed as calculating a PDF trace based on a measured XRPD pattern of a substance, the PDF trace may also be calculated based on a composite XRPD pattern generated from two or more measured XRPD patterns. If certain individual powder patterns have a number of diffraction peaks in common, the pattern comparison system disclosed in US 2004/0103130 A1, published on May 27, 2004, to Ivanisevic et al., the contents of which are incorporated by reference herein, may match and average them, leading to a composite pattern. Amorphous solid forms may also be matched, using general intensity envelopes. An embodiment of the invention therefore comprises calculating the PDF trace of a composite XRPD pattern. The invention also includes comparing the PDF trace calculated from of a composite XRPD pattern to other PDF traces in the manner disclosed herein.

The following Examples illustrate further embodiments of the present invention and application of the embodiments to a variety of practical circumstances.

### EXAMPLE 1

An embodiment of the invention comprises generating a plurality of solid samples of a substance, such as a chemical compound, preparing XRPD patterns of the solid samples, calculating the corresponding PDF traces of the solid samples, and grouping the plurality of PDF traces by similarly into two or more groups. The PDF traces may be grouped, for example, using hierarchical cluster analysis. The grouping of PDF traces by similarity into different groups can identify those samples likely having the same solid form (within each group) and those likely having different solid forms (between groups). The pattern matching technique disclosed in US 2004/0103130 A1 may be used to group together PDF traces that most likely represent the same solid form. A subsequent step could involve practicing an aspect of the embodiment of Example 4 of comparing the PDF trace of one or more of the resulting solid forms to the PDF trace of a known solid form of the substance to determine whether any of the solid forms of the substance made in a production run are new.

### EXAMPLE 2

Another embodiment of the invention comprises generating a plurality of solid samples of a substance, such as a chemical compound, preparing XRPD patterns of the solid samples, calculating the corresponding PDF traces of the solid samples, and comparing the PDF traces to determine whether the samples of the substance have the same or different solid forms. This method, as well as that of Example 1, may be implemented, for example, to manually or in an automated fashion match or distinguish solid forms of samples made in a production run. A subsequent step could involve practicing an aspect of the embodiment of Example 4 of comparing the PDF trace of one or more of the resulting solid forms to the PDF trace of a known solid form of the substance to determine whether any of the solid forms of the substance made in a production run are new.

### EXAMPLE 3

Another embodiment of the invention comprises generating a plurality of solid samples of a substance, such as a chemical compound, preparing XRPD patterns of the solid samples, grouping the plurality of XRPD patterns of the substance by similarly into two or more groups, creating a composite XRPD pattern for each group, calculating the corresponding PDF trace of each of the composite XRPD patterns, and comparing the PDF traces to determine whether the groups of samples represent the same or different solid form of the substance. The XRPD patterns may be grouped by similarity using the pattern matching technique disclosed US 2004/0103130 A1. A subsequent step could involve practicing an aspect of the embodiment of Example 4 of comparing the PDF trace of one or more of the resulting solid forms to the PDF trace of a known solid form of the substance to determine whether any of the solid forms of the substance made in a production run are new.

### EXAMPLE 4

Another embodiment of the invention comprises generating one or more solid test samples of a substance, such as a chemical compound, preparing XRPD patterns of the one or more solid test samples, calculating the corresponding PDF traces of the one or more solid test samples, and comparing one or more of the PDF traces of the test samples to the PDF trace of a known solid form of the substance to determine whether the test samples are of the same or different solid form as the known solid form.

This embodiment may be used, for example, to determine if a solid form produced from a production run is a disordered relative of a known solid form, or if it is a new solid form. This embodiment may also be used to screen various solid forms on the basis of their PDF trace. For instance, the present invention comprises a method of screening for new solid forms of a substance, which comprises providing the PDF trace of each of a plurality of samples of the substance, comparing the PDF traces of the samples to the PDF traces of one or more known solid forms of the substance, and identifying those samples that have a PDF trace different from that of the known solid forms.

### EXAMPLE 5

It is often desirable to know which crystalline solid form is the parent of a given disordered crystalline material. Another embodiment of the invention therefore comprises calculating the PDF trace of a disordered crystalline solid form of a substance and comparing it to the PDF trace of the another crystalline sample of the substance, for example one having a known crystalline solid form, to determine whether the two substances have the same solid form, being related through disorder, or whether the two have different solid forms.

When matching PDF transforms between crystalline and disordered crystalline material, the range of the PDF transform in real space should be truncated to below the average crystal size in the disordered material in order to maximize the match score. Inspection of the PDF transform from the disordered material may identify the maximum real space range to be matched. The pattern comparison system may set the maximum range to the real space distance where the PDF transform for the disordered material falls to a flat zero line. Typically for most small and medium organic molecules this distance is between 15 Angstroms and 30 Angstroms for very disordered material.

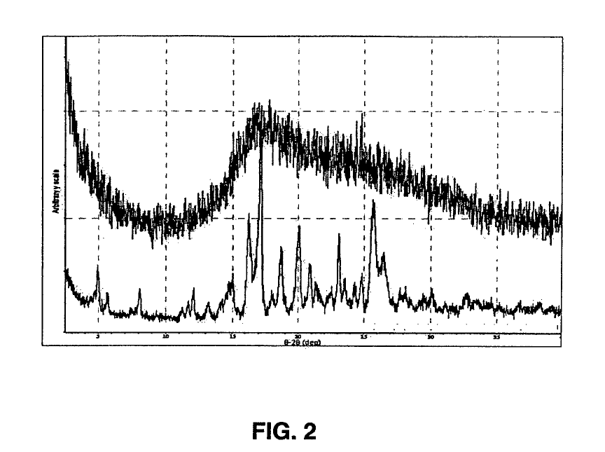

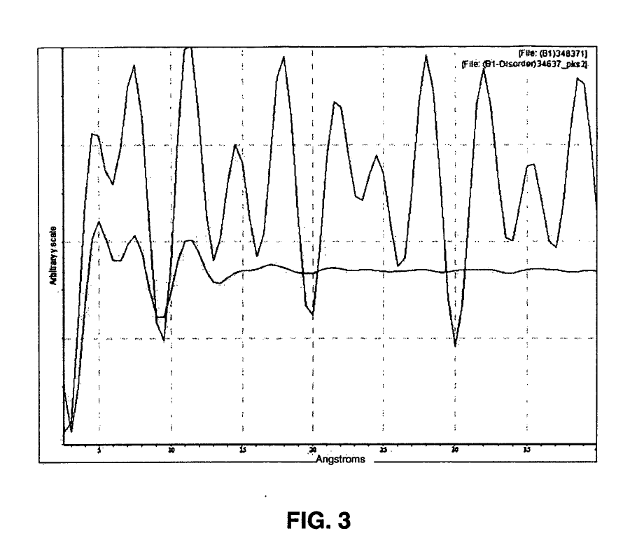

An example of the use of PDF in establishing order-disorder relationships between patterns is demonstrated in FIGS. 2 and 3. FIG. 2 illustrates a typical disordered XRPD pattern (top) and how it compares to the XRPD pattern of a highly crystalline compound (bottom). It is difficult to determine the exact relationship between the two purely through visual inspection of the XRPD patterns, as the peaks in the disordered pattern are quite broad.

Upon applying the PDF to both patterns, one obtains FIG. 3, which clearly illustrates that the two forms are in fact related, being of the same solid form. The top pattern is the PDF trace of the highly crystalline compound, while the bottom pattern is the PDF trace of the disordered pattern. One observes that the peaks below 20 Angstroms match well. After that, the disordered pattern loses long range order, which is indicative of the fact that the crystal size for the disordered material is probably around 20 Angstroms and that the disordered material contains small crystals of the same solid form that produced the other pattern.

### EXAMPLE 6

Another embodiment of the invention comprises identifying residual crystalline “memory” within an amorphous matrix of a substance. The matching of a PDF trace of the amorphous substance to the PDF trace of a related crystalline substance can be a powerful technique in this regard. Very often, amorphous material will retain some residual crystallinity, which can act like destabilizing seeds driving amorphous material to relax more rapidly towards a crystalline form. Residual crystalline memory is most usually seen when the amorphous material has been produced through mechanical processing like cryogrinding, but may also be seen in amorphous material produced from the melt.

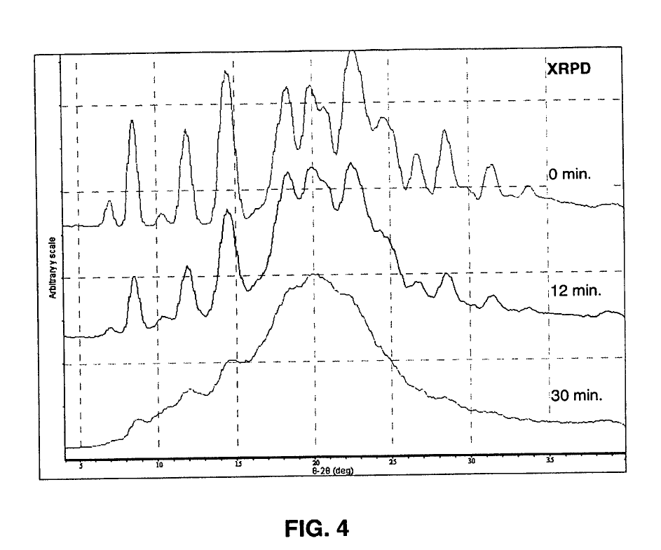

FIG. 4 illustrates XRPD patterns of a compound before cryogrinding (top, 0 minutes), after 12 minutes of cryogrinding (middle) and after 30 minutes of cryogrinding (bottom). Cryogrinding forces the crystalline material to spontaneously collapse region by region to an amorphous form, resulting in a crystalline-amorphous mixture. Continued grinding reduces the presence of the crystalline component.

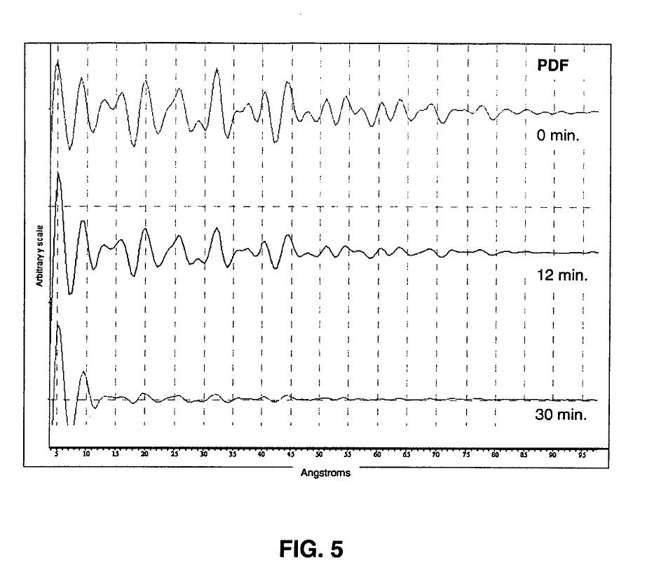

It can be difficult, especially after extended cryogrinding, to determine from inspection of the XRPD patterns whether the cryoground materials contain the original crystalline material. FIG. 5 illustrates the corresponding PDF traces of the materials before cryogrinding (top) after 12 minutes of cryogrinding (middle) and after 30 minutes of cryogrinding (bottom). A comparison of the PDF traces clearly shows that the two cryoground substances retain residual crystallinity of the original crystalline substance.

### EXAMPLE 7

Another embodiment of the invention comprises determining the crystalline correlation length of a disordered crystalline substance. A PDF trace derived from an XRPD pattern of a disordered crystalline substance will show a fall off in signal at larger atom-atom distances. By tracing the signal fall off to the base line, an estimation of the crystalline correlation length can be achieved. This correlation length can be contrasted to the length scale extracted from the observed peak broadening in the XRPD pattern using the Scherrer equation.

A regression analysis of PDF peak signal values can be used to determine the crystal correlation lengths (crystal size or crystal perfection) by 1) determining peak signal in PDF peaks as a function of atom-atom distance, 2) performing linear regression least squares best estimate of line through the peak signal values, and 3) determining atom-atom distance where the best estimate line crosses the base line of the PDF plot. The base line of the PDF plot is y=0.0. If a PDF is available for the crystalline substance, then a comparison between the PDF trace from the crystalline substance and the PDF trace from the disordered substance can be used to isolate those peaks whose loss of signal follows the same trend. Performing regression analysis on these correlated peak signals will give effective crystalline correlation lengths in different crystallographic directions.

We claim:

1. A method which comprises
providing a PDF trace of a first sample of a substance,
providing a PDF trace of a second sample of the substance, and
comparing the PDF traces to determine whether the substance of the first sample and the substance of the second sample have the same or different solid forms.

2. A method as claimed in claim 1, wherein the substance is a chemical compound.

3. A method as claimed in claim 2, wherein the substance is a pharmaceutical compound.

4. A method as claimed in claim 3, wherein the pharmaceutical compound is a pharmaceutically acceptable salt.

5. A method as claimed in claim 1, wherein the substance is a mixture of two or more chemical compounds.

6. A method as claimed in claim 5, wherein the substance is a cocrystal.

7. A method as claimed in claim 5, wherein a compound in the mixture is water and the substance is a hydrate.

8. A method as claimed in claim 1, wherein the substance of at least one sample is disordered crystalline, and which comprises comparing the PDF traces to determine whether the substance of the first sample and the substance of the second sample have the same solid form, being related through disorder.

9. A method as claimed in claim 1, wherein the solid form of the substance of the first or second sample is a known solid form of the substance.

10. A method as claimed in claim 1, wherein at least one of the PDF traces is calculated based on a composite X-ray powder diffraction pattern derived from two or more measured X-ray powder diffraction patterns of the sample.

11. A method of screening for new solid forms of a substance, which comprises
providing a PDF trace of each of a plurality of test samples of a substance,
providing one or more PDF traces of known solid forms of the substance,
comparing the PDF traces of one or more of the test samples to one or more of the PDF traces of known solid forms to identify any substances in the test samples that have a new solid form.

12. A method which comprises
providing a PDF trace of each of a plurality of test samples of a substance, and
grouping the plurality of PDF traces of the substance by similarity into two or more groups through hierarchical cluster analysis.

13. A system which comprises
means for providing a PDF trace of a first sample of a substance,
means for providing a PDF trace of a second sample of the substance, and
means for comparing the PDF traces to determine whether the substance of the first sample and the substance of the second sample have the same or different solid forms.

14. A computer-readable medium comprising instructions for performing the method as claimed in claim 1.
